(19) United States
(12) Patent Application Publication
(10) Pub. No.: US 2026/0182436 A1
(43) Pub. Date: Jun. 25, 2026

(54) MODULATED PROTECTIVE STRUCTURE USED FOR POWER MODULE, POWER MODULE, AND METHOD OF FORMING POWER MODULE

(71) Applicant: PowerX Semiconductor Corporation, Hsinchu County (TW)

(72) Inventors: Wei Chung HUANG, Hsinchu County (TW); Jing-Yao CHANG, Hsinchu County (TW)

(21) Appl. No.: 19/096,669

(22) Filed: Mar. 31, 2025

(30) Foreign Application Priority Data
Dec. 24, 2024 (TW) 113150476

(51) Int. Cl. H01L 23/00; H01L 23/31

(52) U.S. Cl. CPC H10W 74/111; H10W 72/07502; H10W 72/07531; H10W 72/5434; H10W 90/754

(57) ABSTRACT

A modulated protective structure for a power module includes a copper foil and at least one sintering layer. The copper foil has a plurality of first holes. The sintering layer is formed on the copper foil, and the at least one sintering layer does not overlap the first holes of the copper foil in a cross-section view. The at least one sintering layer is configured to bond the copper foil to a chip of the power module. The plurality of first holes are configured to be over a gate bus of the chip and arranged along the gate bus in a top view.

### CROSS-REFERENCE TO RELATED APPLICATION

This application claims priority to Taiwan Application Serial Number 113150476, filed Dec. 24, 2024, which is herein incorporated by reference in their entirety.

### BACKGROUND

### Field of Invention

The present disclosure relates to a modulated protective structure used for a power module, a power module, and a method of forming a power module.

### Description of Related Art

A power module is a package including multiple power devices (such as semiconductor chips). The power devices can be disposed on a substrate, and the electrodes on the power devices are connected to a specific terminal through traces. Applications of power modules are frequently found in transportation systems. For example, power modules can be used in components, such as motor drivers, inverters, converters, power supplies, etc. However, when different devices are bonded together, the device may be damaged due to process conditions. For example, a gate bus of a semiconductor chip may break by excessive stress during the process. Therefore, there is a need to develop a method that can be used to reduce the stress level encountered by a semiconductor chip during the process.

### SUMMARY

A modulated protective structure for a power module is provided. The modulated protective structure includes a copper foil and at least one sintering layer. The copper foil has a plurality of first holes. The at least one sintering layer is formed on the copper foil, and the at least one sintering layer does not overlap the plurality of first holes of the copper foil in a cross-sectional view. The at least one sintering layer is configured to bond the copper foil to a chip of the power module, and the plurality of first holes are configured to be over a gate bus of the chip and arranged along the gate bus in a top view.

The present disclosure provides a power module. The power module includes a chip and a modulated protective structure. The chip includes a source pad, a gate pad, and a gate bus. The gate bus is adjacent to the source pad and electrically connected to the gate pad. The modulated protective structure is on the chip. The modulated protective structure includes at least one sintering layer and a copper foil. The at least one sintering layer is disposed on the source pad. The copper foil has a plurality of first holes. The first holes of the copper foil are configured to be over the gate bus of the chip and arranged along the gate bus in a top view.

The present disclosure further provides a method of forming a power module. The method includes forming a plurality of first holes in a copper foil; forming a plurality of sintering layer on the copper foil, in which the plurality of first holes do not overlap the plurality of sintering layers in a top view; cutting the copper foil into a modulated protective structure, in which the modulated protective structure including at least one of the plurality of sintering layers and a part of the plurality of first holes; and bonding the modulated protective structure to a chip, in which the modulated protective structure is bonded to a source pad of the chip by using the at least one of the plurality of sintering layers, and the part of the plurality of first holes are configured to be over a gate bus of the chip and arranged along the gate bus of the chip in the top view.

It is to be understood that both the foregoing general description and the following detailed description are by examples, and are intended to provide further explanation of the disclosure as claimed.

### BRIEF DESCRIPTION OF THE DRAWINGS

FIG. 1 to FIG. 3 depict top views of a protective structure during a process of manufacturing the protective structure according to some embodiments of the present disclosure.

FIG. 4 depicts a cross-sectional view of a power module during a process of forming the power module according to some embodiments of the present disclosure.

FIG. 5 depicts a top view of a power module during a process of forming the power module according to some embodiments of the present disclosure, and FIG. 4 is a cross-sectional view taken along a line A-A′ in FIG. 5.

FIG. 6 to FIG. 8 depict cross-sectional views of a power module during a process of forming the power module according to some embodiments of the present disclosure.

FIG. 9 depicts a cross-sectional view of a power module during a process of forming the power module according to some other embodiments of the present disclosure.

FIG. 10 depicts a top view of a power module during a process of forming the power module according to some other embodiments of the present disclosure, and FIG. 9 is a cross-sectional view taken along a line A-A′ in FIG. 10.

FIG. 11A to FIG. 11J depict distribution diagrams of holes of a copper foil according to various embodiments of the present disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Some embodiments of the present disclosure relates to a modulated protective structure used for a power module. The modulated protective structure can be composed of a copper foil and sintering layers, and is connected to a top surface of a chip by using a sintering process. The copper foil of the modulated protective structure according to some embodiments of the present disclosure has multiple holes, and these holes can correspond to a gate bus of the chip. Hence, when the modulated protective structure is combined with the chip, the sintering process will not cause too much stress on the gate bus of the chip and damage the gate bus of the chip.

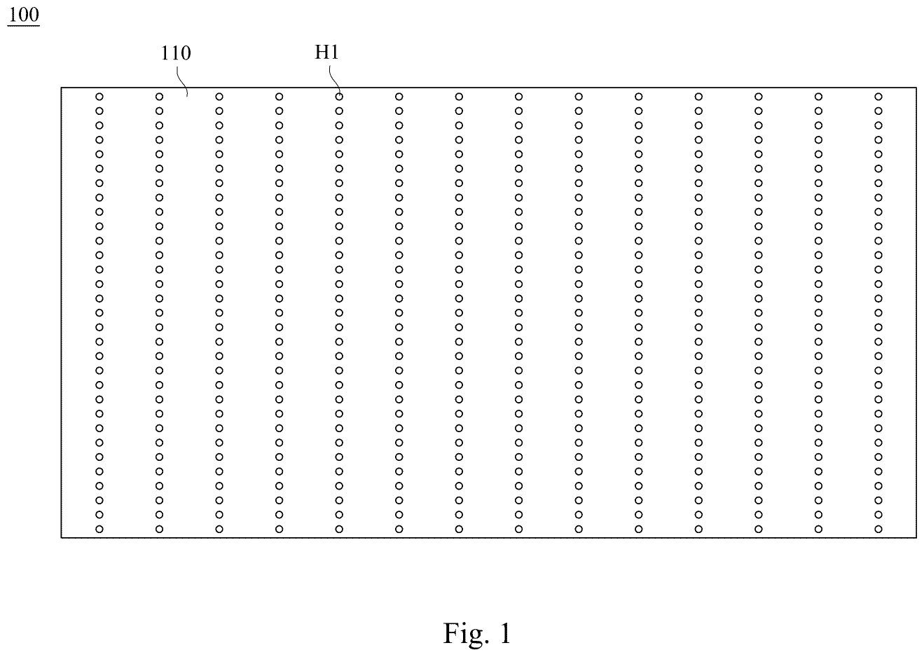

FIG. 1 to FIG. 3 depict top views of a protective structure 100 during a process of manufacturing the protective structure 100 according to some embodiments of the present disclosure. A description is provided with reference to FIG. 1. A copper foil 110 is provided, and a plurality of holes H1 are formed in the copper foil 110. In some embodiments, the copper foil 110 may have any suitable shape. For example, an overall shape of the copper foil 110 is rectangular or circular. In some embodiments, the copper foil 110 may undergo various surface treatments. For example, a surface of the copper foil 110 can be electroplated or chemically plated with metallic nickel, gold, silver, nanotwinned copper, or nanotwinned silver. The holes H1 may be formed by any suitable method. In some embodiments, photolithographic etching, laser drilling, or computer numerical control (CNC) mechanical drilling, etc. can be used to form the holes H1 in the copper foil 110. Each of the holes H1 may have various shapes, and the holes H1 may be arranged in different distribution patterns. In some embodiments, each of the holes H1 may be circular, oval, capsule-shaped, diamond-shaped, square, star-shaped, etc.

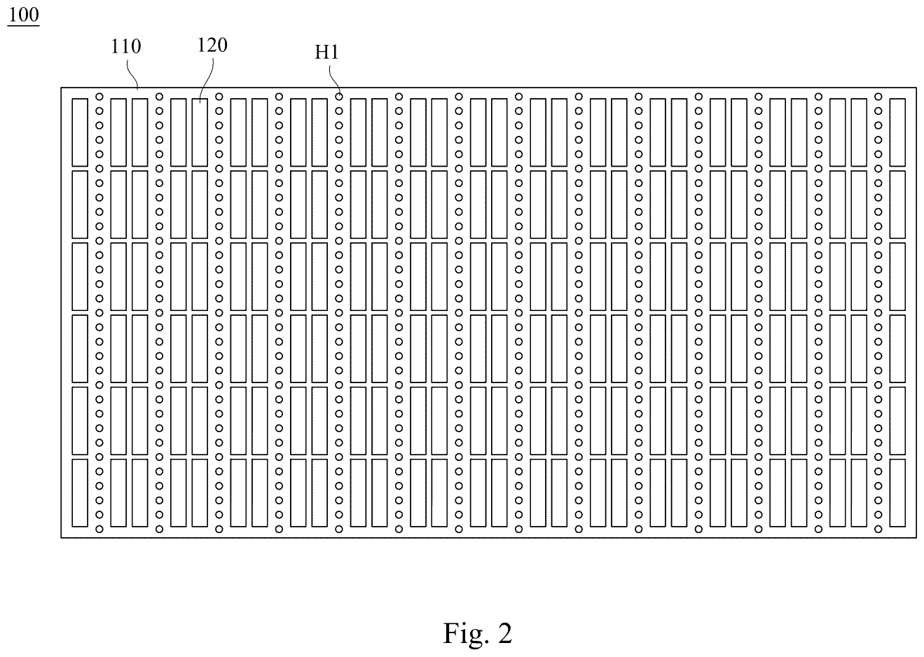

A description is provided with reference to FIG. 2. A plurality of sintering layers 120 are formed on the copper foil 110. The holes H1 do not overlap the sintering layers 120 in the top view. In some embodiments, the sintering layers 120 may be arranged in an array. For example, two columns of sintering layers 120 can be configured between two columns of holes H1. Each of the sintering layers 120 may be in any suitable form. In some embodiments, each of the sintering layers 120 may be sintering paste, a sintering sheet, or a sintering film. In some embodiments, each of the sintering layers 120 may be made of metal, such as silver. In some embodiments, the sintering layers 120 and the copper foil 110 are made of different materials. The sintering layers 120 can be coated on the copper foil 110 through printing, spraying, lamination, and mass transfer processes. Next, the sintering layers 120 are fixed onto the copper foil 110 through an adhesion process. In some embodiments, if the sintering layers 120 are sintering paste, the sintering layers 120 can be pre-dried and then fixed onto the copper foil 110. In some other embodiments, if the sintering layers 120 are the sintering paste, the sintering paste can be printed on the copper foil 110 first, and then the sintering layers 120 are pre-dried. For example, the conditions for the above pre-drying process are that the temperature ranges from 60° C. to 140° C. and the time ranges from 5 minutes to 20 minutes. If the sintering layers 120 are the sintering films, the sintering layers 120 can be fixed onto the copper foil 110 under the circumstances that a lamination interface temperature ranges from 120° C. to 150° C., a pressure ranges from 2 MPa to 5 MPa, and a time ranges from 30 seconds to 120 seconds. After the sintering layers 120 are fixed onto the copper foil 110, a cutting protective tape can be affixed to surfaces of the sintering layers 120 that are not in contact with the copper foil 110, so that the sintering layers 120 are not damaged during the subsequent cutting process or the sintering layers 120 do not affect subsequent cutting process.

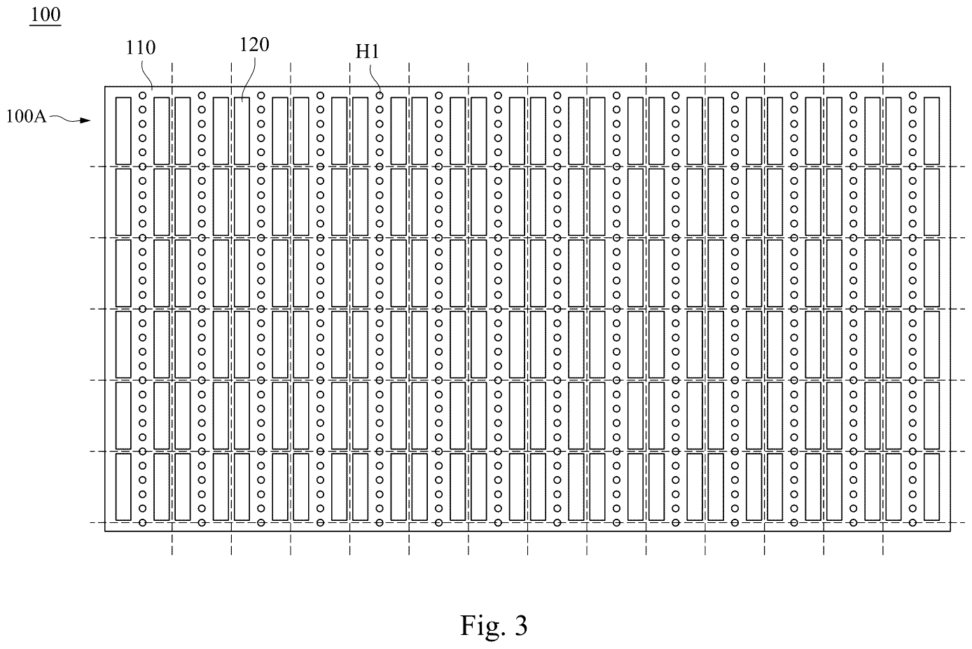

A description is provided with reference to FIG. 3. Through cutting the copper foil 110, the protective structure 100 is divided into a plurality of modulated protective structures 100A. Each of the modulated protective structures 100A includes the copper foil 110, at least one of the plurality of sintering layers 120, and a part of the plurality of holes H1. In greater detail, the copper foil 110 to which the sintering layers 120 have been adhered can be cut and divided through sawing, laser cutting, stamping, etching, or water jet cutting. For example, the copper foil 110 can be cut along the dotted lines shown in FIG. 3, and each of the modulated protective structures 100A can include two sintering layers 120 and one column of holes H1 arranged along a gap between the two sintering layers 120. Each of the modulated protective structures 100A that has been cut and divided is packaged, and the packaging form may be a wafer, a waffle pack, or a tape and reel.

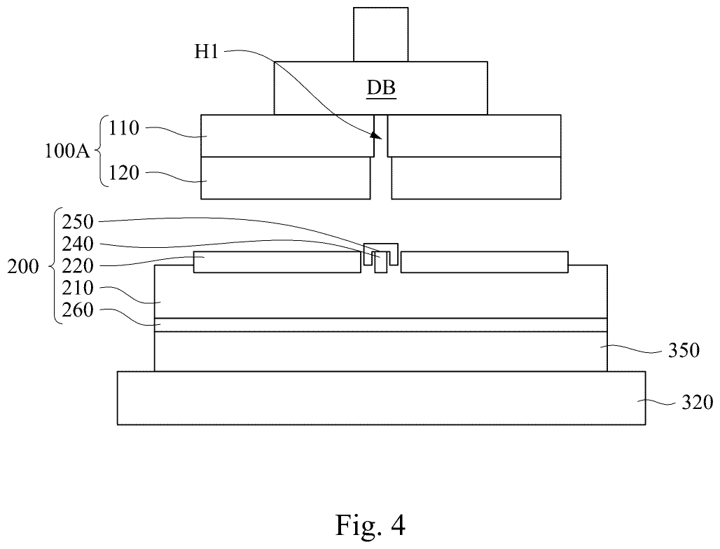

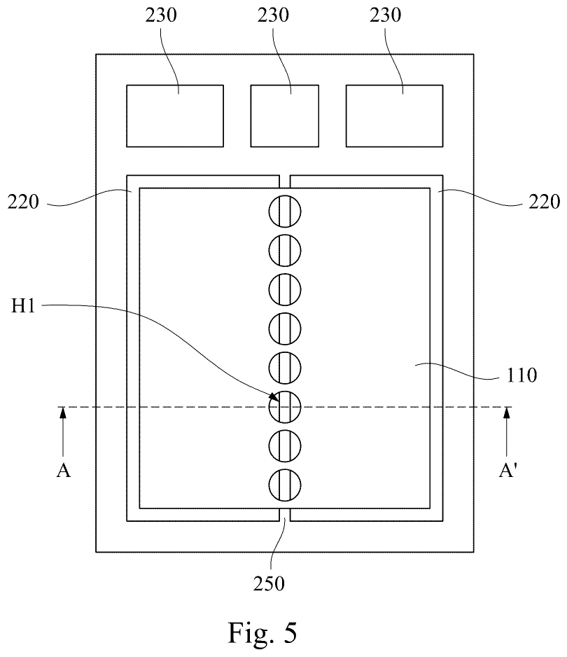

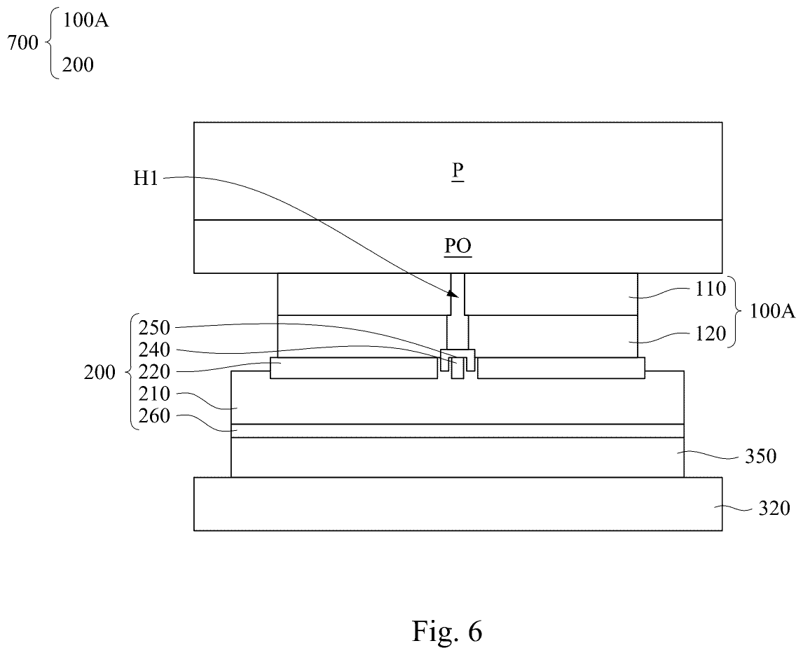

FIG. 4 depicts a cross-sectional view of a power module during a process of forming the power module according to some embodiments of the present disclosure. FIG. 5 depicts a top view of a process of a power module of a process of forming the power module according to some embodiments of the present disclosure, and FIG. 4 is a cross-sectional view taken along a line A-A′ in FIG. 5. FIG. 6 to FIG. 8 depict cross-sectional views of a power module during a process of forming the power module according to some embodiments of the present disclosure. A description is provided with reference to FIG. 4 and FIG. 5. The modulated protective structure 100A is bonded to a chip 200 to form a power module 700 (see FIG. 6). The chip 200 may include a semiconductor layer 210, source pads 220, gate pads 230 (see FIG. 5), a gate bus 240, a protective layer 250, and a drain pad 260. The semiconductor layer 210 may include a plurality of doped regions in it, and the different doped regions can be electrically connected to different devices. The source pads 220, the gate pads 230, and the gate bus 240 are on a same side of the semiconductor layer 210. The gate bus 240 may be adjacent to the source pads 220. As can be seen from the top view of the chip 200 (FIG. 5), the source pads 220 can be located on a lower half of the chip 200, and the gate pads 230 can be located on an upper half of the chip 200. The source pads 220 and the gate bus 240 can be connected to different doped regions, respectively, and the source pads 220 and the gate bus 240 are electrically isolated. The gate bus 240 is further electrically connected to the gate pads 230.

In some embodiments, the number of source pads 220 may be two and the number of gate pads 230 may be three, but the present disclosure is not limited thereto. In some embodiments, the gate bus 240 may be disposed between two source pads 220. The protective layer 250 covers the gate bus 240 and is used to protect the gate bus 240, and the protective layer 250 does not cover the source pads 220 and the gate pads 230. The drain pad 260 and the source pads 220 are on opposite sides of the semiconductor layer 210. In some embodiments, the semiconductor layer 210 may be made of a semiconductor material, such as silicon or silicon carbide. Each of the source pads 220, the gate pads 230, the gate bus 240, and the drain pad 260 may be made of a conductor, such as metal. The protective layer 250 may be made of a dielectric material, such as silicon oxide. In some embodiments, the chip 200 may be bonded to a metal layer 320 of a substrate by using a sintering layer 350 in advance.

When the modulated protective structure 100A is bonded to the chip 200, the modulated protective structure 100A are bonded to the source pads 220 of the chip 200 through at least one of the sintering layers 120. Referring to FIG. 4, the holes H1 of the copper foil 110 do not overlap the sintering layers 120 in the cross-sectional view, and the sintering layers 120 do not overlap the gate bus 240 in the cross-sectional view. The holes H1 of the copper foil 110 are configured to be over the gate bus 240 of the chip 200. As shown in FIG. 5, the holes H1 of the copper foil 110 are arranged along the gate bus 240 of the chip 200 in the top view. It should be noted that since the gate bus 240 is covered by the protective layer 250, the holes H1 of the copper foil 110 are depicted to be arranged along the protective layer 250 in FIG. 5.

According to some embodiments of the present disclosure, the number of sintering layers 120 included in each of the modulated protective structures 100A corresponds to the number of source pads 220 of the chip 200. In greater detail, the number of sintering layers 120 included in each of the modulated protective structures 100A is equal to the number of source pads 220 of the chip 200, and each of the sintering layers 120 contacts one source pad 220 when the modulated protective structure 100A is bonded to the chip 200.

In greater detail, during the process of bonding the modulated protective structure 100A to the chip 200, a temporary die bonding process can be performed first, and then a permanent bonding process is performed to bond the modulated protective structure 100A to the chip 200. The temporary die bonding process is shown in FIG. 4. The packaged modulated protective structure 100A can undergo a hot pressing process of a die bonder DB to temporarily fix the sintering layers 120 of the modulated protective structure 100A to the source pads 220 on the surface of the chip 200. In some embodiments, the temperature of the temporary die bonding process is from 100° C. to 160° C., the pressure of the temporary die bonding process is from 0.5 MPa to 4 MPa, and the time of the temporary die bonding process is from 200 milliseconds to 2000 milliseconds.

A description is provided with reference to FIG. 6. After the temporary die bonding process is performed, the permanent bonding process can be performed to permanently bond the sintering layers 120 of the modulated protective structure 100A to the source pads 220 on the surface of the chip 200. In greater detail, a polymer layer PO can be placed on the copper foil 110, and then a pressure head P is used to apply a specific pressure and temperature to the copper foil 110, so as to ensure that the sintering layers 120 of the modulated protective structure 100A are permanently bonded to the source pads 220 on the surface of the chip 200. In some embodiments, the polymer layer PO may be a polytetrafluoroethylene (PTFE) layer. In some embodiments, the temperature of the permanent bonding process is from 200° C. to 300° C., the pressure of the permanent bonding process is from 5 MPa to 30 MPa, and the time of the permanent bonding process is from 1 minute to 5 minutes. After the permanent bonding process is completed, the polymer layer PO can be removed.

Generally speaking, if a modulated protective structure does not have a specific design for protecting the gate bus 240, the stress induced by the permanent bonding process will probably cause the gate bus of the chip underneath to break. As a result, the gate pads are in poor contact with the underlying doped regions in the semiconductor layer. According to the embodiment of the present disclosure, when the modulated protective structure 100A is bonded to the chip 200, the holes H1 are over the gate bus 240 of the chip 200, and as seen from the top view, the holes H1 are arranged along the gate bus 240 of the chip (in FIG. 5, along the protective layer 250 that covers the gate bus 240 is depicted). Hence, when the permanent bonding process is performed, the stress generated by the copper foil 110 on the gate bus 240 of the chip 200 is less and does not cause too much damage to the gate bus 240 of the chip 200. In addition, the sintering layers 120 of the modulated protective structure 100A do not overlap the gate bus 240 of the chip 200. As a result, when the permanent bonding process is performed, the sintering layers 120 densified by diffusion will not cause too much damage to the gate bus 240.

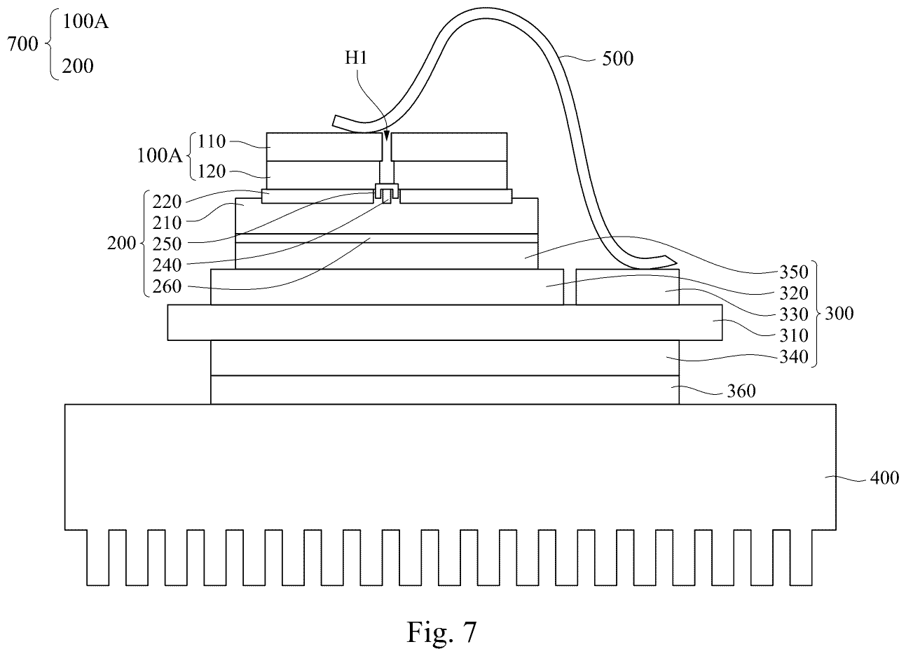

A description is provided with reference to FIG. 7. The chip 200 is bonded to a substrate 300. In some embodiments, the chip 200 may be bonded to the substrate 300 before the modulated protective structure 100A is bonded to the chip 200. The substrate 300 may include a carrier 310, and further include a metal layer 320, a metal layer 330, and a metal layer 340 which are coated on surfaces of the carrier 310. The metal layer 320 and the metal layer 330 are on a same side of the carrier 310. The metal layer 320 and the metal layer 340 are on opposite sides of the carrier 310. The chip 200 can be bonded to the metal layer 320 of the substrate 300 by using the sintering layer 350. In greater detail, the metal layer 320 can be electrically connected to drain pad 260 of chip 200. In some embodiments, before the chip 200 is bonded to the substrate 300, the metal layer 340 of the substrate 300 may be bonded to a base plate 400 by using a sintering layer 360 in advance. In some embodiments, the substrate 300 may be made of an insulating material, such as ceramic. Each of the metal layer 320, the metal layer 330, and the metal layer 340 may be made of a suitable metal, such as copper. Each of the sintering layer 350 and the sintering layer 360 may be made of silver.

After that, the modulated protective structure 100A is bonded to the substrate 300 by using a bonding wire 500. In greater detail, the bonding wire 500 connects the copper foil 110 of the modulated protective structure 100A and the metal layer 330 of the substrate 300 to provide an electrical connection between the source pads 220 of the chip 200 and the metal layer 330 of the substrate 300. In some embodiments, the bonding wire 500 can be across at least one hole H1 in the top view. In some embodiments, the bonding wire 500 may be a copper wire or a copper ribbon. In some embodiments, the diameter of the hole H1 is 0.2 millimeters (mm). In the embodiment where the bonding wire 500 is the copper wire, the diameter of the bonding wire 500 is 0.4 mm. In the embodiment where the bonding wire 500 is the copper ribbon, the diameter of the bonding wire 500 is 1 mm.

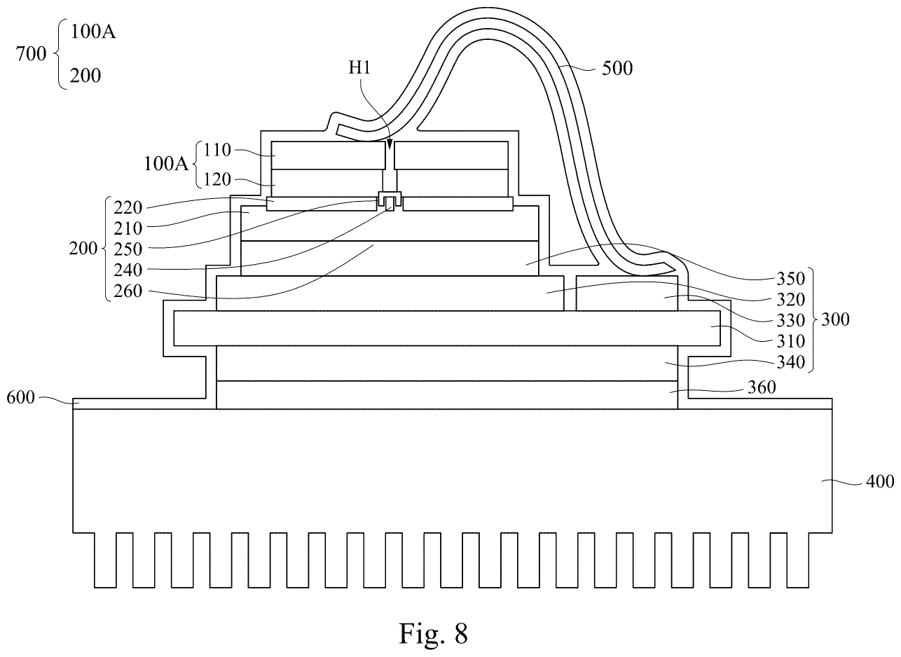

A description is provided with reference to FIG. 8. An encapsulation material 600 that covers the modulated protective structure 100A, the chip 200, the substrate 300, the base plate 400, and the bonding wiring 500 is formed, and the encapsulation material 600 extends into the holes H1. The encapsulation material 600 further contacts the protective layer 250, and is used to protect the gate bus 240 to improve the reliability of the gate bus 240. In some embodiments, the encapsulation material 600 may be a polymer material with high fluidity, so it can easily flow into the holes H1.

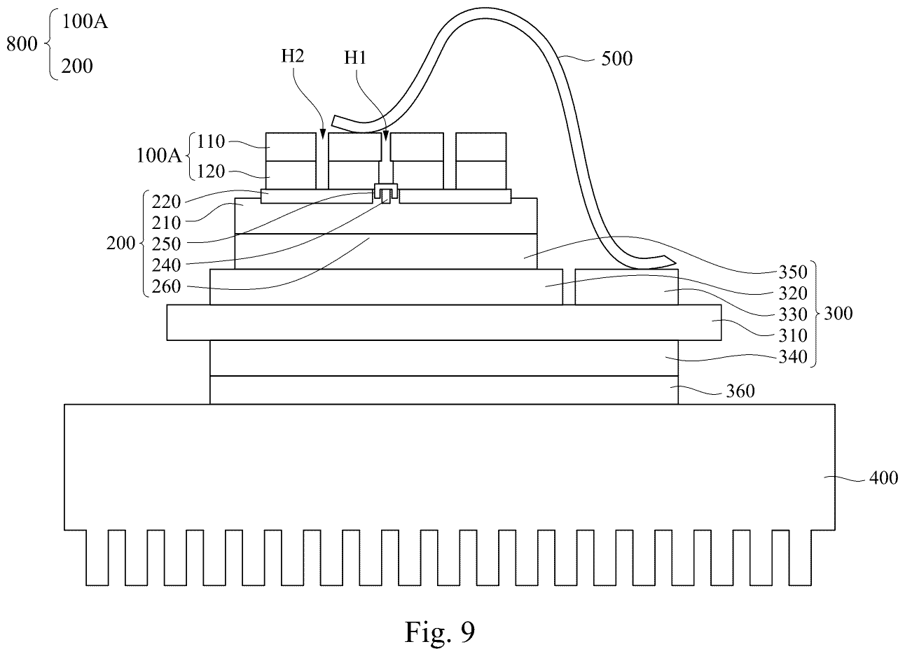

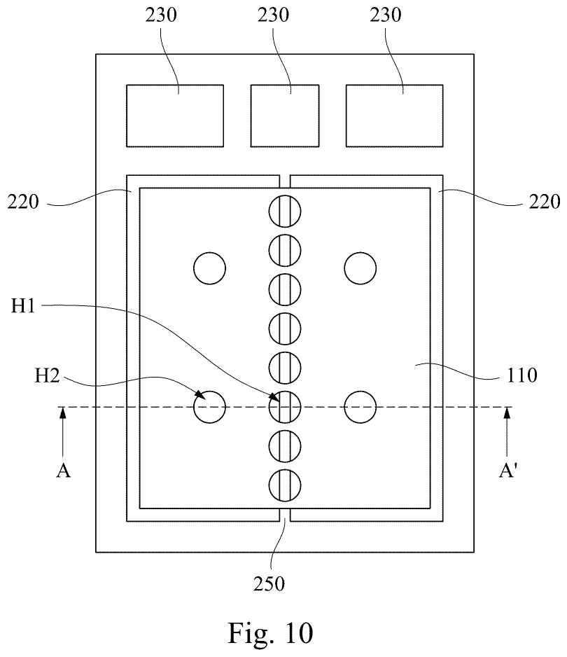

FIG. 9 depicts a cross-sectional view of a power module during a process of forming the power module according to some other embodiments of the present disclosure. FIG. 10 depicts a top view of a power module during a process of forming the power module according to some other embodiments of the present disclosure, and FIG. 9 is a cross-sectional view taken along a line A-A′ in FIG. 10. A description is provided with reference to FIG. 9. The modulated protective structure 100A is bonded to the chip 200 to form a power module 800. The power module 800 in FIG. 9 to FIG. 10 differs from the power module 700 in FIG. 4 to FIG. 8 in that the copper foil 110 of the modulated protective structure 100A in FIG. 9 to FIG. 10 further includes a plurality of holes H2 to improve stress relief effect. The sintering layers 120 do not overlap the holes H2 of the copper foil 110 in the cross-sectional view. When the modulated protective structure 100A is bonded to the chip 200, the holes H2 of the copper foil 110 are configured to be over the source pads 220 of the chip 200 of the power module. Each of the holes H2 may have various shapes and the holes H2 may be in different arrangements and combinations. In some embodiments, each of the holes H2 may be circular, oval, capsule-shaped, diamond-shaped, square, star-shaped, etc.

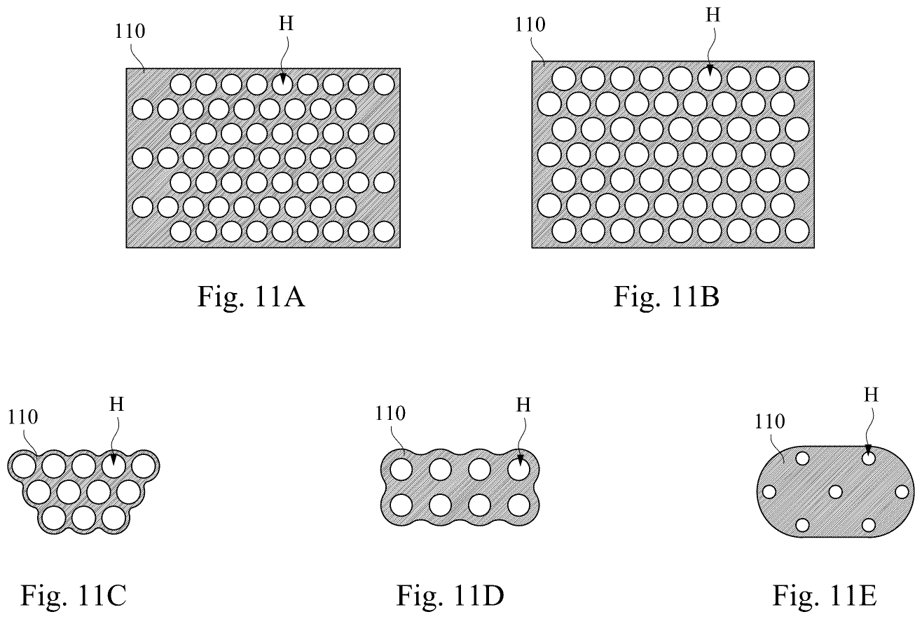

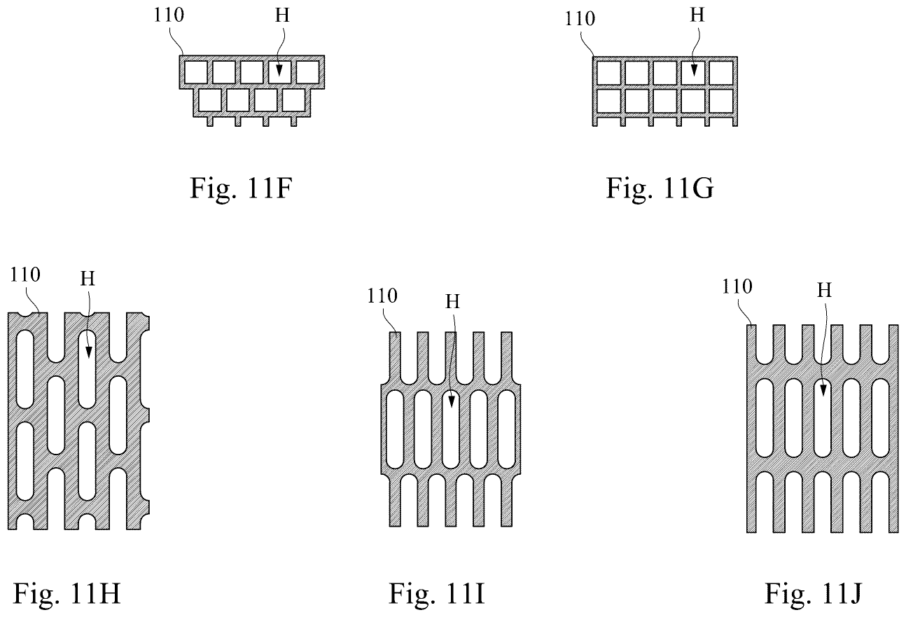

FIG. 11A to FIG. 11J depict distribution diagrams of holes H of the copper foil 110 according to various embodiments of the present disclosure. In FIG. 11A to FIG. 11J, the holes H are the collective name of the holes H1 and the holes H2 mentioned above. A description is provided with reference to FIG. 11A. Each of the holes H may be circular, and the holes H are arranged in a plurality of rows. The holes H in each of the rows are not aligned with the holes H in adjacent rows, and the positions of the holes H in each of the rows are offset relative to the positions of the holes H in the adjacent rows. In greater detail, each hole H is aligned with the center point of the line connecting the centers of two adjacent holes H in one adjacent row. The arrangement of the holes H in FIG. 11B is similar to the arrangement of the holes H in FIG. 11A. A difference between these two arrangements is that the holes H in each of the rows in FIG. 11A are more offset from the holes H in the adjacent rows, and the holes H in each of the rows in FIG. 11B are less offset from the holes H in the adjacent rows.

Referring to FIG. 11C, the holes H can be circular, and the holes H can be arranged in a trapezoidal shape. Referring to FIG. 11D, the holes H can be circular, and the holes H can be arranged in a plurality of rows. The holes H in each of the rows can be aligned with the holes H in the adjacent rows. As shown in FIG. 11E, the copper foil 110 can be capsule-shaped. The holes H can be circular, one of the holes H is located at a center point of the copper foil 110, and the other holes H are located at the edge of the copper foil 110. Additionally, one of the holes H at the edge of the copper foil 110 is symmetrical with another one of the holes H at the edge of the copper foil 110 with respect to the hole H at the center point of the copper foil 110.

Referring to FIG. 11F, the copper foil 110 can be irregularly shaped. The holes H can be square, and the holes H can be arranged in a trapezoidal shape. Referring to FIG. 11G, the copper foil 110 can be rectangular. The holes H can be square, and the holes H can be arranged in a plurality of rows. The holes H in each of the rows can be aligned with the holes H in adjacent rows. Referring to FIG. 11H, the holes H can be capsule-shaped, and the holes H are arranged in a plurality of rows. The holes H in each of the rows are not aligned with the holes H in adjacent rows, and the holes H in each of the rows are offset along a lengthwise direction of the holes H relative to the holes H in the adjacent rows. In greater detail, some of the holes H are aligned with center points of lines connecting centers of two adjacent holes H in each of the adjacent rows. Referring to FIG. 11I, the holes H can be capsule-shaped, and the holes H are arranged in a plurality of rows. The holes H in each of the rows are not aligned with the holes H in adjacent rows (the holes H in each of the rows are completely staggered with the holes H in the adjacent rows), and the holes H in each of the rows are offset along a transverse direction of the holes H (that is, the shorter dimension of the holes H) relative to the holes H in the adjacent rows. In greater detail, some of the holes H are aligned with center points of lines connecting centers of two adjacent holes H in each of the adjacent rows. Referring to FIG. 11J, the copper foil 110 can be rectangular. The holes H can be capsule-shaped, and the holes H can be arranged in a plurality of rows. The holes H in each of the rows can be aligned with the holes H in adjacent rows.

It is noted that FIG. 11A to FIG. 11J depict the distribution diagrams of the holes H of the copper foil according to various embodiments. However, as long as a part of the holes H (for example, the holes H1 in FIG. 5) are located over the gate bus of the chip and are arranged along the gate bus in the top view after the modulated protective structure is bonded to the chip, the copper foil of the modulated protective structure according to the present disclosure can reduce the stress caused on the gate bus during the bonding process (such as the temporary die bonding process in FIG. 4 and the permanent bonding process in FIG. 6) to avoid breakage of the gate bus.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A modulated protective structure for a power module comprising:
a copper foil having a plurality of first holes; and
at least one sintering layer formed on the copper foil, wherein the at least one sintering layer does not overlap the plurality of first holes of the copper foil in a cross-sectional view, and wherein the at least one sintering layer is configured to bond the copper foil to a chip of the power module, and the plurality of first holes are configured to be over a gate bus of the chip and arranged along the gate bus in a top view.

2. The modulated protective structure of claim 1, wherein the copper foil further comprises a plurality of second holes, the plurality of second holes of the copper foil are configured to be over a source pad of the chip.

3. The modulated protective structure of claim 2, wherein the at least one sintering layer does not overlap the plurality of second holes in the cross-sectional view.

4. The modulated protective structure of claim 1, wherein the at least one sintering layer comprises a plurality of sintering layers, and the plurality of first holes are arranged along at least one gap between the plurality of sintering layers.

5. A power module comprising:
a chip comprising:
a source pad;
a gate pad; and
a gate bus adjacent to the source pad and electrically connected to the gate pad; and
a modulated protective structure on the chip, wherein the modulated protective structure comprises:
at least one sintering layer disposed on the source pad; and
a copper foil having a plurality of first holes, wherein the first holes are configured to be over the gate bus of the chip and arranged along the gate bus in a top view.

6. The power module of claim 5, wherein the at least one sintering layer does not overlap the plurality of first holes in a cross-sectional view.

7. The power module of claim 5, wherein the copper foil further comprises a plurality of second holes, the plurality of second holes of the copper foil are over the source pad of the chip.

8. The power module of claim 7, wherein the at least one sintering layer does not overlap the plurality of first holes and the plurality of second holes of the copper foil in a cross-sectional view.

9. The power module of claim 5, wherein the at least one sintering layer does not overlap the gate bus in a cross-sectional view.

10. The power module of claim 5, further comprising:
an encapsulation material covering the modulated protective structure and the chip.

11. The power module of claim 10, wherein the encapsulation material extends into the plurality of first holes of the copper foil.

12. The power module of claim 5, further comprising:
a substrate underneath the chip; and
a bonding wire connecting the copper foil of the modulated protective structure and the substrate.

13. The power module of claim 12, wherein the bonding wire is across at least one of the plurality of first holes in the top view.

14. A method of forming a power module comprising:
forming a plurality of first holes in a copper foil;
forming a plurality of sintering layers on the copper foil, wherein the plurality of first holes do not overlap the plurality of sintering layers in a top view;
cutting the copper foil into a modulated protective structure, wherein the modulated protective structure comprises at least one of the plurality of sintering layers and a part of the plurality of first holes; and
bonding the modulated protective structure to a chip, wherein the modulated protective structure is bonded to a source pad of the chip by using the at least one of the plurality of sintering layers, and the part of the plurality of first holes are configured to be over a gate bus of the chip and arranged along the gate bus of the chip in the top view.

15. The method of claim 14, further comprising:
bonding the chip to a substrate; and
forming an encapsulation material on the modulated protective structure and the chip, wherein the encapsulation material extends into the part of the plurality of first holes.

16. The method of claim 15, further comprising:
bonding the chip to the substrate; and
bonding the modulated protective structure to the substrate by using a bonding wire.

17. The method of claim 16, wherein the bonding wire is across at least one of the part of the plurality of first holes in the top view.

18. The method of claim 14, wherein the plurality of sintering layers do not overlap the gate bus in a cross-sectional view when the modulated protective structure is bonded to the chip.

19. The method of claim 14, further comprising:
forming a plurality of second holes in the copper foil, wherein the second holes of the copper foil are configured to be over the source pad of the chip when the modulated protective structure is bonded to the chip.

20. The method of claim 14, wherein bonding the modulated protective structure to the chip comprises:
performing a temporary die bonding process, wherein a temperature of the temporary die bonding process is from 100° C. to 160° C.; and
performing a permanent bonding process, wherein a temperature of the permanent bonding process is from 200° C. to 300° C.
